(19) United States
(12) Patent Application Publication
(10) Pub. No.: US 2007/0003782 A1
(43) Pub. Date: Jan. 4, 2007

(54) COMPOSITE EMP SHIELDING OF BULK-SOLIDIFYING AMORPHOUS ALLOYS AND METHOD OF MAKING SAME

(76) Inventor: KENNETH STEVEN COLLIER, DADE CITY, FL (US)

Correspondence Address: CHRISTIE, PARKER & HALE, LLP, PO BOX 7068, PASADENA, CA, 91109-7068, US

(21) Appl. No.: 10/545,757

(22) PCT Filed: Feb. 23, 2004
(86) PCT No.: PCT/US04/05068

§ 371 Date: Apr. 27, 2006

Related U.S. Application Data
(60) Provisional application No. 60/449,198, filed on Feb. 21, 2003.

(51) Int. Cl. H05K 9/00; B32B 15/00; B21D 39/00; B22D 17/08

(52) U.S. Cl. 428/621; 428/615; 174/394; 164/113

(57) ABSTRACT

An electromagnetic pulse (EMP) and high power microwave (HPM) shielding enclosure made of bulk-solidifying amorphous alloys and composites with high hardness, corrosion resistance, high strength-to-weight ratio and high conductivity, and a method of making such shielding enclosures is provided.

### FIELD OF THE INVENTION

The present invention relates to electromagnetic pulse (EMP) and high power microwave (HPM) shielding enclosures made of bulk-solidifying amorphous alloys and composites, and more particularly to such EMP enclosures made from bulk-solidifying amorphous alloys and composites with high hardness, corrosion resistance, high strength-to-weight ratio and high conductivity.

### BACKGROUND OF THE INVENTION

Electromagnetic pulse (EW) and high power microwave (HPM) are one of many products of a nuclear detonation. The gamma rays from the detonation collide with air molecules in the atmosphere creating Compton electrons which move rapidly away from the center of the detonation. This large-scale separation of charges creates a strong nonradiated electric field between the electrons and the parent ions. The movement of these charges produces a Compton current in which the pulse is characterized by electromagnetic fields with short rise times of few nanoseconds and a high peak electric field amplitude of multiple kilovolts per meter. When a high-yield EMP weapon is detonated above the atmosphere, the explosion of EMP has the capability of disabling electric and electronic systems as far as several thousand miles from the detonation site.

As modern electronic components become smaller, more tightly integrated, and more power efficient they become more sensitive to EMP even at a very low intensity and their vulnerability to serious damage from even moderate EMP events increases. Modem weaponry, military vehicles, guidance and information system for missiles, aerospace, and similar devices are becoming more vulnerable to the EMP because they are increasingly dependent on such miniaturized electronic components. As such, EMP shielding and enclosures for these critical electronic components becomes crucial.

EMP shielding takes different shapes and sizes, but generally comprise a structure which encloses the electronic components, protecting them from the effect of an EMP and a HPM from any direction. Indeed, an ideal EMP shield is a topologically continuous and closed structure with high electrical conductivity. However, such structures are typically not feasible due to the requirements for power and signal feed-through, e.g. antennas, as well as due to manufacturing limitations. Accordingly, the gaps and joints in such conventional shielding enclosures degrade the effectiveness of such structures as EMP shields. Moreover, minimizing such gaps and joints in EMP shielding enclosures results in complex manufacturing processes and higher cost.

Shielding effectiveness is also greatly dependent on the frequency of the incident electromagnetic wave radiation and the ability of the electromagnetic wave to penetrate the shield and any gaps within the shield. Specifically, the RF wave starts to attenuate as the gaps in the shield approach sizes on the order of the length of the wavelength of the electromagnetic wave radiation. For example, the RF wave attenuates at a given rate of 20 dB per decade ( 1/10 of the cut-off frequency), or 6dB per octave (½ of cut-off frequency). The higher the frequency, the smaller the gap must be and preferably the structure of the shielding enclosure can be constructed with as few openings as possible. It is difficult to construct a shielding case with few opening using conventional alloy because stamping cannot produce complex shape and machining is very expensive. In addition, casting of conventional metal and alloy into any complex shape is either impossible or very costly for the purposes of reducing the dimensions of the gaps.

Furthermore, the enclosure of the modern electronics should provide protection against physical and environmental intrusion, as they may face harsh conditions such as salt, acid, and caustic environments. For exarnple, in conventional weapon systems, such as the MK 45, which is used aboard ships, the shield must provide protection from environmental EMP contamination that originates from the ship's normal operations, as well as from hostile action while preventing corrosion of the electronics from ocean salt. Such electronics devices are also used in mobile units, and may be subjected to high g forces, as well as physical impact and intrusion. Needless to say, some structural damage to the enclosure, even though still adequate to protect the enclosed electronics physically, can easily compromise the EMP shielding effectiveness by increasing the existing gaps in the joints. As such these enclosures should provide structural integrity and protection, and should do so with minimum weight penalty.

Conventional materials used in electronic enclosures are deficient at address the above mentioned issues. Pure metals, such as aluminum and copper, though having high electrical conductivity and good formability to make enclosures with reduced joints and gaps, do not have the sufficient strength to sustain structural integrity without becoming prohibitively heavy. Meanwhile, typical high strength alloys suffer from reduced EMP shielding because of these materials' lower electrical conductivity. In addition, issues arise due to the complexities involved in the manufacture of these materials, as well as with the possible corrosion and rusting of such materials when exposed to harsh environmental conditions. For example, high strength alloys are difficult to cast into net-shape enclosure components with thin sections and few openings. Moreover, due to the high strength of these materials the formability of these alloys into complex geometries is highly compromised. Finally, although plastics have good manufacturing characteristics, these materials suffer from inadequate strength and structural stability, and further lack sufficient electrical conductivity.

Accordingly, there is a need for improved shielding enclosures, and improved materials to produce such enclosure structures.

### SUMMARY OF THE INVENTION

The present invention is directed to an electromagnetic pulse (EMP) and high power microwave (HPM) shielding enclosure made of bulk-solidifying amorphous alloys and composites with high hardness, corrosion resistance, high strength-to-weight ratio and high conductivity.

In one embodiment of the invention, a method of fabricating EMP shielding comprise of the following steps: 1) a feed stock of molten alloy is provided at above Tm; 2) introduce the molten alloy to the die cavity; 3) quench and take the part out of the die cavity; and 4) coat surface with a highly conductive layer.

In another embodiment of the invention, a method of fabricating EMP shielding comprise of the following steps: 1) a feed stock of amorphous alloy in amorphous phase is provided; 2) heat the feed stock to above Tm, but below Tg; 3) shape the heated feed stock into desired shape and cool; and 4) coat surface with a highly conductive layer.

In still another embodiment of the invention, the EMP shield design composite structure comprises at least one piece made of a bulk solidifying amorphous alloy.

In yet another embodiment of the invention, the composite structure is coated with a highly conductive layer.

In still yet another embodiment of the invention, the highly conductive layer is coated on the outside surface of the composite structure. In another such embodiment of the invention, the inner surface of the shield can be further coated with a non-electrical-conductive material. In such an embodiment, the said non-electrical-conductive material may be a good thermal conductive material.

In still yet another embodiment the bulk solidifying amorphous alloy composition is selected from the group consisting of Ti-base, Zr/Ti base, and Fe-base. In one such embodiment, the Zr/Ti base bulk-solidifying amorphous alloy has in-situ ductile crystalline precipitates.

In still yet another embodiment of the provided bulk solidifying amorphous alloy composition has a critical cooling rate of 100° C./second or less and preferably 10° C./second or less.

In still yet another embodiment of the provided bulk solidifying amorphous alloy composition has a delta T (Tx-Tg) of at least 60° C. or greater.

In still yet another embodiment of the invention, the composite structure is a near net-shape cast component further coated with a highly conductive metal. In one such embodiment, the bulk-solidifying amorphous alloy is cast or molded into near-to-net shape EMP shield structure.

In another embodiment of the invention, the EMP shielding composite structure is a casting or molding of bulk-solidifying amorphous alloy.

### BRIEF DESCRIPTION OF THE DRAWINGS

These and other features and advantages of the present invention will become appreciated as the same becomes better understood with reference to the specification, claims and drawings wherein:

FIGS. 3 and 4 are flowcharts of exemplary embodiments of methods for manufacturing EMP shields in accordance with the present invention.

FIG. 1 is a schematic of an exemplary embodiment of an EMP enclosure in accordance with the present invention.

FIG. 2 is a schematic of an exemplary embodiment of an EMP shield material in accordance with the present invention.

### DETAILED DESCRIPTION OF THE INVENTION

The object of the current invention is an EMP shielding enclosure made of bulk-solidifying amorphous alloys and composite with high hardness, corrosion resistance, high strength-to-weight ratio and high electrical conductivity. Another object of the invention is shielding enclosures made of bulk-solidifying amorphous alloys and composites providing improved ruggedness, environmental durability, lightweight structures and effective EMP shielding. Still another object of the invention is method of producing such structures made of bulk-solidifying amorphous alloys and composites.

Bulk solidifying amorphous alloys are recently discovered family of amorphous alloys, which can be cooled at substantially lower cooling rates, of about 500 K/sec or less, and retain their amorphous atomic structure substantially. As such, they can be produced in thickness of 1.0 mm or more, substantially thicker than conventional amorphous alloys of typically 0.020 mm which require cooling rates of 10⁵ K/sec or more U.S. Pat. Nos. 5,288,344;5,368,659;5,618,359; and 5,735,975, the disclosures of which are incorporated by reference in their entirety, disclose such bulk solidifying amorphous alloys.

On exemplary family of bulk solidifying amorphous alloys can be described as (Zr,Ti)a(Ni,Cu,Fe)b(Be,Al,Si,B)c, where a is in the range of from about 30 to 75, b is in the range of from about 5 to 60, and c in the range of from about 0 to 50 in atomic percentages. Furthermore, these alloys can accommodate substantial amounts of other transition metals up to 20% atomic, and more preferably metals such as Nb, Cr, V, Co. A preferable alloy family is (Zr,Ti)a(Ni,Cu)b(Be)c, where a is in the range of from about 40 to 75, b is in the range of from about 5 to 50, and c in the range of from about 5 to 50 in atomic percentages. Still, a more preferable composition is (Zr,Ti)a(Ni,Cu)b(Be)c, where a is in the range of from about 45 to 65,b is in the range of from about 7.5 to 35, and c in the range of from about 10 to 37.5 in atomic percentages. Another preferable alloy family is (Zr)a(Nb,Ti)b(Ni,Cu)c(Al)d, where a is in the range of from about 45 to 65,b is in the range of from about 0 to 10, c is in the range of from about 20 to 40 and d in the range of from about 7.5 to 15 in atomic percentages.

Another set of bulk-solidifying amorphous alloys are ferrous metals (Fe, Ni, Co) based compositions. Examples of such compositions are disclosed in U.S. Pat. No. 6,325,868, and publications to (A. Inoue et. al., Appl. Phys. Lett., Volume 71, p 464(1997)), (Shen et. al., Mater. Trans., JIM, Volume 42, p 2136 (2001)), and Japanese patent application 2000126277 (Publ. # 2001303218 A). One exemplary composition of such alloys is Fe72Al5Ga2P11C6B4. Another exemplary composition of such alloys is Fe72Al7Zr20Mo5W2B15. Although, these alloy compositions are not processable to the degree of Zr-base alloy systems, they can be still be processed in thicknesses around 1.0 mm or more, sufficient enough to be utilized in the current invention.

In general, crystalline precipitates in bulk amorphous alloys are highly detrimental to their properties, especially to the toughness and strength, and as such are generally kept to as small a volume fraction as possible. However, there are cases in which, ductile crystalline phases precipitate in-situ during the processing of bulk amorphous alloys, which are indeed beneficial to the properties of bulk amorphous alloys especially to the toughness and ductility. Such bulk amorphous alloys comprising such beneficial precipitates are also included in the current invention. One exemplary case is disclosed in (C. C. Hays et. al, Physical Review Letters, Vol. 84,p 2901, 2000).

Typically, bulk solidifying amorphous alloys have relatively lower electrical conductivity (electrical resistivity on the order of 200micro-ohm.cm) than highly regarded conductive metals, such as copper and aluminum, and as such are not regarded usable for EMP shielding enclosures.

Bulk-solidifying amorphous alloys also typically have high strength and high hardness, and as such can provide structural integrity and protection against physical intrusion. For example, Zr and Ti-base amorphous alloys have typical yield strengths of 250 ksi or higher and hardness values of 450 Vickers or higher. The ferrous-base version can have yield strengths up to 500 ksi or higher and hardness values of 1000 Vickers and higher. As such, these alloys display very high strength-to-weight ratio, especially in the case of Ti-base and Fe-base alloys. Furthermore, bulk-solidifying amorphous alloys have good corrosion resistance and environmental durability, especially alloys that are Zr and Ti based.

The inventors surprisingly discovered that, even though bulk-solidifying amorphous alloys are alone not regarded highly for EMP shielding, novel composites of bulk-solidifying amorphous alloys can be made into shielding enclosures providing improved ruggedness, environmental durability, lightweight structures and effective EMP shielding. Furthermore, such structures can be produced into more complex and effective geometries and with favorable cost factors, and as such can utilize and exploit various design considerations in shielding enclosures.

EMP shielding effectiveness depends on two main mechanisms: absorption and reflection. Reflection losses, which are from the property changes at the interfaces, arepractically independent of the material thickness, and are directly proportional to the log of inverse of frequency; therefore, the lower the frequency, the larger the shielding effectiveness in this mode of shielding. Furthermore, reflection losses are also directly proportional to the log of the electrical conductivity of the material used in shielding enclosure, and accordingly the higher the conductivity of the shielding, the more effective the shielding.

On the other hand, absorption losses are directly proportional to the thickness of the material. Absorption losses are also directly proportional to the square root of the electrical conductivity of the material used in shielding enclosure, and accordingly the higher the conductivity, the better is the shielding effectiveness. Furthermore, absorption losses are directly proportional to the square root of the frequency; therefore, the higher the frequency, the larger the shield effectiveness in this mode of shielding.

The composite structure according to the current invention comprises a relatively thick layer made of a bulk solidifying amorphous alloy. The composite structure also comprises a thin surface layer of a high conductivity metal coated onto the bulk-solidifying amorphous alloy. The highly conductive metal is preferably a pure metals, such as copper, aluminum, nickel, tungsten and molybdenum. The advantages of this composite structure for effective EMP shielding include:
The low-to-mid range frequency spectrum EMP power will be diminished substantially by reflection losses at the interface of the composite material. Herein, examples of the interfaces are the interface between the amorphous alloy and highly conductive layer, and the interface between the conductive layer and the ambient atmosphere. The interfaces of conductive layer will also act to diminish the low-to-mid range frequency spectrum EMP power by the reflection loss mechanism, and will do so much more effectively due to its high conductivity and since the reflection loss mechanism works more efficiently at low-to-mid range frequency. As such, the low-to-mid range frequency spectrum of the EMP power will be cut-off by reflection loss mechanism utilizing the interfaces of the highly conductive layer and the mid-to-high spectrum will be left for diminishment.
The mid-to-high range frequency spectrum of the EMP power will be substantially diminished by absorption losses. The relatively thicker layer of the bulk-solidifying amorphous alloys provides a longer path for the extinguishing of the mid-to-high range frequency spectrum of the EMP power. Although the electrical conductivity of the amorphous alloys may not be as high as desirable, the relatively thicker layer of the bulk-solidifying amorphous alloys will be effective in shielding the mid-to-high end frequency spectrum of the EMP power since the absorption mechanism works much more effectively for the mid-to-high range frequency spectrum.

Accordingly, the disclosed composite structure and its various elements work in conjunction to cut-off the opposing spectrum of the EMP power, and as such cut off the whole EMP frequency spectrum. The highly conductive thinner layer, will act primarily to cut-off the low-to-mid range frequency by reflection loss mechanism, and the thicker amorphous layer, will act to cut-off the mid-to-high range frequency by absorption loss mechanism.

The composite structure and the shielding enclosures of the current invention also have other advantages as shielding enclosures for the electronic components mentioned above. The bulk-solidifying amorphous layer, with its high-strength, will provide the necessary structural support and integrity for the shielding enclosure, and will perform this function better than conventional metals and alloys. Furthermore, the high-strength-to-weight ratio, especially for Ti and Fe-base alloys, of the bulk-solidifying amorphous alloys will provide lightweight structures providing weight savings for mobile systems. The combination of high strength and high hardness of the bulk solifying-amorphous alloys further provides protection against physical intrusion and mechanical impact.

Moreover, the combination of the physical and mechanical parameters of the enclosures according to the current invention, namely the effective structural support and integrity, and protection against physical intrusion and mechanical impact will be crucial in maintaining the continuity of the highly conductive layer, a critical factor in preserving the effectiveness of the EMP shielding. The high strength and high hardness of the bulk-solidifying amorphous alloys will provide an effective support for the highly conductive thin layer against deformation and piercing, and as such will maintain the continuity of the highly conductive layer.

The proposed composite material has also other advantages for corrosion and environmental durability. The relatively high inertness and high corrosion resistance of the bulk-solidifying amorphous alloys will provide protection to the sub-structure of the enclosure against environmental effects such as rusting. Furthermore, due to high inertness and high corrosion resistance, bulk-solidifying amorphous alloys are compatible with highly conducting metals such as copper, alumininum, nickel, tungsten and molybdenum, and as such make such composite structures viable. Typical incompatibilities, as seen in other composite structures of multi-material systems will be significantly reduced. All these advantages are also beneficial for the long-life effectiveness of EMP shielding.

FIGS. 1 and 2 show schematics of the composite structure of the EMP shielding enclosure according to the present invention. FIG. 1, merely shows an outer view of a potential enclosure structure 10; however, as shown in FIG. 2, the walls of the composite structure of the EMP shielding enclosure 10 generally comprises a relatively thick layer of bulk-solidifying amorphous alloy layer 12 and a relatively thin highly conductive metal 14. The highly conductive layer can be made of any metal and alloys that posses good electrical conductivity such as Cu, Ag, Al, Mo, W and other metals and alloys. The thickness of the coating may range from 10-500 μm, and preferably between 50-200 μm.

Although the highly conductive layer can be both on the inner an outer surfaces of the bulk-solidifying amorphous layer, in one preferred embodiment of the invention, the outer surface of bulk solidifying amorphous alloy is coated with the highly conductive metal. In this configuration, reflective losses resulting from the conductive layer will be better leveraged to cut-off the low-to-mid range frequency spectrum, which is less affected during absorption losses. Meanwhile, the mid-to-high range frequency spectrum, which is less affected by the reflection losses, will be cut-off by leveraging the relatively thick layer of bulk solidifying amorphous alloy.

In another embodiment of the invention, not shown in the Figures, in order to avoid accidental shortage or arcing between the shielding structure and the electrical component, the inner surface of the shielding structure can be further coated with a coating of non-electrical-conductive layer.

The bulk solidifying amorphous alloys have very high elastic strain limits, typically around 1.8% or higher. This is an important characteristic of bulk-solidifying amorphous alloys for the use and application of EMP shielding, and a preferred one for protecting any electrical article subject to any mechanical loading. The high elastic strain limit allows the joint to be thinner and lighter, which is a characteristic absent in other shielding materials. In the case of conventional metals and alloys with much lower elastic strain limit, the use of larger and much more rigid shields is needed to sustain both global and local loading as well as to maintain the integrity of EMP shielding; therefore, a large amount of weight is added to the system. In general, larger shield and rigid shielding structures are highly undesirable due to the increased in weight and bulkiness. On the other hand, bulk solidifying amorphous alloy has very high strength to weight ratio and elastic limit in which less material with lighter weights can be use to obtain the same or better strength and shield effectiveness requirements.

The invention is also directed to methods of making shielding enclosures from the composites of bulk-solidifying amorphous alloys. The capability of manufacturing net-shape complex components is another advantage of using bulk solidifying amorphous alloys, and results in significantly reduced manufacturing and assembling costs, and improves the EMP shielding effectiveness by having fewer separated parts per component, and therefore, fewer gaps for the EMP to penetrate the enclosure. In addition, the dimensions of the gap along the physical joints can be reduced with tighter manufacturing tolerances at reduced costs so that EMP shielding effectiveness can be improved. Furthermore, geometric factors, such as ribs can be incorporated into the structure for better structural integrity, and as such the durability of the shielding structure across physical joints can be improved and the tighter and smaller dimensions of the gap can be preserved. The bulk-solidifying amorphous alloy EMP shielding structure can be fabricated by either casting amorphous alloys or molding amorphous alloys prior to coating it with a conductive layer. The conductive coating layer can be coated by, but not limited to, chemical vapor deposition, combustion chemical vapor deposition, plating, physical deposition, electro-deposition or a combination thereof.

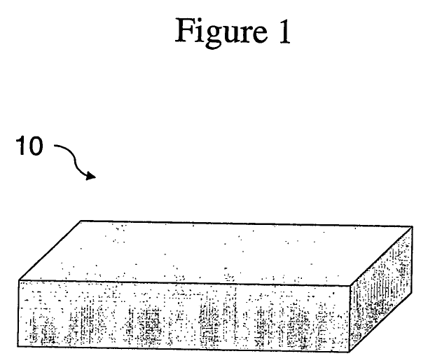

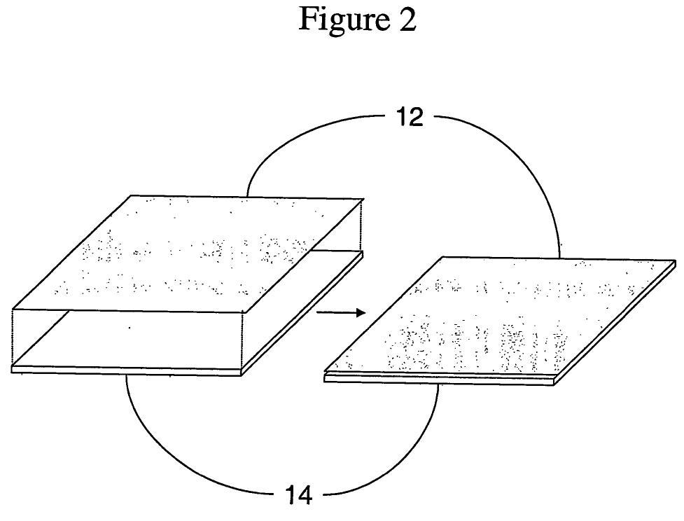

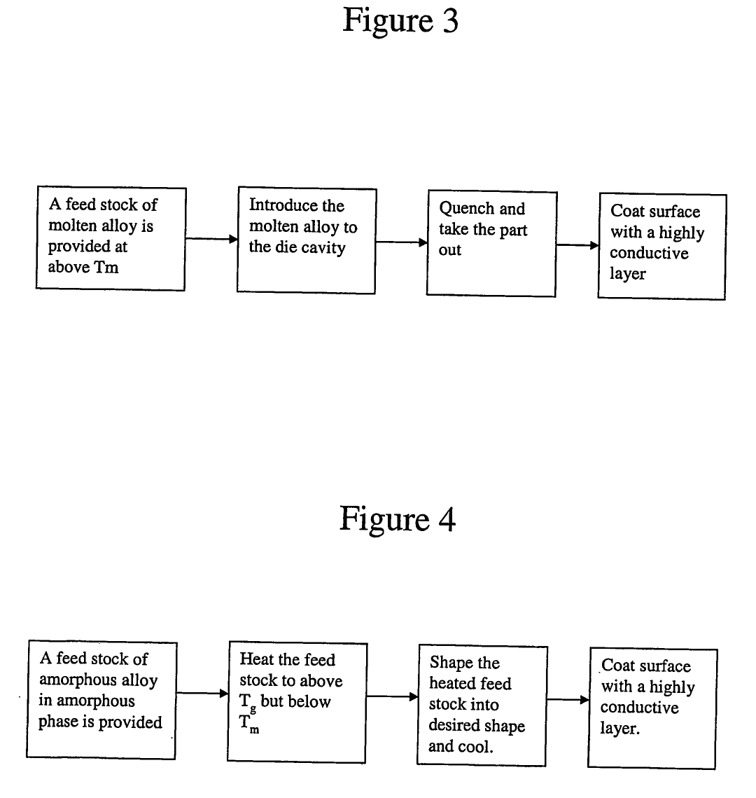

In one exemplary embodiment, the casting process of producing a bulk-solidifying amorphous alloy EMP shielding structure comprises the following steps: 1) a feed stock of molten alloy is provided at above Tm; 2) the molten alloy is introduced into the die cavity; 3) the molten alloy is quenched and the part removed; and 4) the surface is coated with a highly conductive layer. A flow chart of this exemplary process is shown in FIG. 3.

In another exemplary embodiment, the molding process of producing bulk-solidifying amorphous alloy EMP shielding structures is comprised of the following steps: 1) a feed stock of amorphous alloy in amorphous phase is provided; 2) the feed stock is heated to above T_{g} but below Tₘ; 3) the heated feed stock is shaped into the desired shape and cooled; and 4) the surface is coated with a highly conductive layer. A flow chart of this exemplary process is shown in FIG. 4.

While several forms of the present invention have been illustrated and described, it will be apparent to those of ordinary skill in the art that various modifications and improvements can be made without departing from the spirit and scope of the invention. Accordingly, it is not intended that the invention be limited, except as by the appended claims.

What is claimed is:

1. An electromagnetic pulse and high power microwave shield comprising an at least partial enclosure having inner and outer surfaces, wherein the enclosure is formed of a composite material comprising at least one layer of a bulk-solidifying amorphous alloy and at least one highly conductive layer, and wherein the bulk-solidifying amorphous alloy layer is thicker than the highly conductive layer.

2. The shield described in claim 1, wherein the highly conductive layer comprises a material selected from the group consisting of Cu, Ag, Al, Mo, W and alloys thereof.

3. The shield described in claim 1, wherein the highly conductive layer has a thickness of from 10-500 μm.

4. The shield described in claim 1, wherein the highly conductive layer is coated on the outside surface of the composite structure.

5. The shield described in claim 1, wherein the inner surface of the shield is further coated with a non-electrical-conductive layer.

6. The shield described in claim 5, wherein the non-electrical-conductive material is a good thermal conductive material.

7. The shield described in claim 1, wherein the bulk solidifying amorphous alloy composition is selected from the group consisting of Ti-base, Zr/Ti base, and Fe-base alloys.

8. The shield described in claim 7, wherein the bulk solidifying amorphous alloy comprises a Zr/Ti base alloy having in-situ ductile crystalline precipitates.

9. The shield described in claim 1, wherein the bulk solidifying amorphous alloy composition has a critical cooling rate of 100° C./second or less.

10. The shield described in claim 1, wherein the bulk solidifying amorphous alloy composition has a critical cooling rate of 10° C./second or less.

11. The shield described in claim 1, wherein the bulk solidifying amorphous alloy composition has a delta T (Tx-Tg) of at least 60° C. or greater.

12. A method of manufacturing electromagnetic pulse and high power microwave shield enclosure comprising:
providing a feed stock of a molten bulk-solidifying amorphous alloy at a temperature above the melting temperature of the bulk-solidifying amorphous alloy;
introducing the molten bulk-solidifying amorphous alloy to a die cavity;
quenching the molten bulk-solidifying amorphous alloy to form an enclosure at a cooling rate sufficiently fast such that the alloy maintains a substantially amorphous atomic structure; and
coating at least one surface of the enclosure with a layer of a highly conductive material.

13. The method described in claim 12, wherein the highly conductive layer comprises a material selected from the group consisting of Cu, Ag, Al, Mo, W and alloys thereof.

14. The method described in claim 12, wherein the highly conductive layer has a thickness of from 10-500 μm.

15. The method described in claim 12, wherein the highly conductive layer is coated on the outside surface of the composite structure.

16. The method described in claim 12, further comprising coating the inner surface of the shield with a non-electrical-conductive layer.

17. The method described in claim 16, wherein the non-electrical-conductive material is a good thermal conductive material.

18. The method described in claim 12, wherein the bulk solidifying amorphous alloy composition is selected from the group consisting of Ti-base, Zr/Ti base, and Fe-base alloys.

19. The method described in claim 18, wherein the bulk solidifying amorphous alloy comprises a Zr/Ti base alloy having in-situ ductile crystalline precipitates.

20. The method described in claim 12, wherein the bulk solidifying amorphous alloy composition has a critical cooling rate of 100° C./second or less.

21. The method described in claim 12, wherein the bulk solidifying amorphous alloy composition has a critical cooling rate of 10° C./second or less.

22. The method described in claim 12, wherein the bulk solidifying amorphous alloy composition has a delta T (Tx-Tg) of at least 60° C. or greater.

23. A method of manufacturing electromagnetic pulse and high power microwave shield enclosure comprising:
providing a feedstock of a bulk solidifying amorphous alloy in an amorphous phase;
heating the feedstock to a temperature between the melting temperature and the glass transition temperature of the bulk solidifying amorphous alloy;
shaping the heated feedstock into an enclosure;
cooling the shaped enclosure; and
coating at least one surface of the enclosure with a layer of a highly conductive material.

24. The method described in claim 23, wherein the highly conductive layer has a thickness of from 10-500 μm.

25. The method described in claim 23, wherein the highly conductive layer is coated on the outside surface of the composite structure.

26. The method described in claim 23, further comprising coating the inner surface of the shield with a non-electrical-conductive layer.

27. The method described in claim 26, wherein the non-electrical-conductive material is a good thermal conductive material.

28. The method described in claim 23, wherein the bulk solidifying amorphous alloy composition is selected from the group consisting of Ti-base, Zr/Ti base, and Fe-base alloys.

29. The method described in claim 28, wherein the bulk solidifying amorphous alloy comprises a Zr/Ti base alloy having in-situ ductile crystalline precipitates.

30. The method described in claim 23, wherein the bulk solidifying amorphous alloy composition has a critical cooling rate of 100° C./second or less.

31. The method described in claim 23, wherein the bulk solidifying amorphous alloy composition has a critical cooling rate of 10° C./second or less.

32. The method described in claim 23, wherein the bulk solidifying amorphous alloy composition has a delta T (Tx-Tg) of at least 60° C. or greater.
